(19) United States
(12) Patent Application Publication
(10) Pub. No.: US 2024/0385431 A1
(43) Pub. Date: Nov. 21, 2024

(54) LASER BEAM ASTIGMATISM EVALUATING METHOD

(71) Applicant: DISCO CORPORATION, Tokyo (JP)

(72) Inventor: Atsushi MAEDA, Tokyo (JP)

(21) Appl. No.: 18/648,920

(22) Filed: Apr. 29, 2024

(30) Foreign Application Priority Data
May 19, 2023 (JP) 2023-083016

(51) Int. Cl. G02B 27/00; B23K 26/03; B23K 26/08; B23K 103/00; C30B 33/04; G01M 11/02

(52) U.S. Cl. CPC G02B 27/0068; B23K 26/032; B23K 26/0892; C30B 33/04; G01M 11/02; B23K 2103/56

(57) ABSTRACT

A evaluating method includes forming a plurality of processing traces each having a spot shape by irradiating different positions of an exposed surface of a workpiece with a laser beam according to respective height positions of a condensing point by moving a condenser for the laser beam and the workpiece relative to each other along a first direction as a direction of irradiation of the workpiece with the laser beam and thereby positioning the condensing point at a plurality of the height positions, and moving the condenser and the workpiece relative to each other along a second direction intersecting the first direction, obtaining an image of each of the processing traces, calculating an aspect ratio of each of the processing traces, and calculating an index indicating a degree of astigmatism on the basis of the plurality of height positions and the aspect ratio of each of the processing traces.

### BACKGROUND OF THE INVENTION

### Field of the Invention

The present invention relates to an evaluating method for evaluating the astigmatism of a laser beam in a laser processing apparatus and the laser processing apparatus that enables the evaluating method to be performed.

### Description of the Related Art

As laser processing using a laser processing apparatus, the following are known: forming a groove in a workpiece by a laser beam having a wavelength absorbed by the workpiece (see Japanese Patent Laid-open No. 2003-320466, for example); and forming a relatively weak modified region within a workpiece by irradiating the workpiece with a laser beam such that the condensing point of the laser beam having a wavelength transmissive through the workpiece is positioned within the workpiece (see Japanese Patent Laid-open No. 2002-192370, for example).

The laser processing apparatus includes a laser beam irradiating unit for irradiating a workpiece with a laser beam. The laser beam irradiating unit includes a laser oscillator and a plurality of optical elements. The laser beam emitted from the laser oscillator is passed through the plurality of optical elements, and is ideally applied to the workpiece in a state in which the laser beam is condensed to one point.

However, the laser beam passed through the plurality of optical elements may not be condensed sufficiently due to an effect of astigmatism caused by the distortion of one or more optical elements or the like. In this case, a problem can occur in that the workpiece is not processed appropriately. Accordingly, it is necessary to evaluate the astigmatism properly and correct the astigmatism when necessary.

For the evaluation of the astigmatism, a method is known which branches a part of the laser beam and irradiates a concave mirror provided in a peripheral portion of a chuck table with the part of the laser beam, guides reflection light from the concave mirror to a beam profiler, and thereby analyzes a spatial intensity distribution of the laser beam (see Japanese Patent Laid-open No. 2021-90990, for example).

In addition, as another method for evaluating the astigmatism, a method is known which branches a part of the laser beam, irradiates the concave mirror provided in the peripheral portion of the chuck table with the part of the laser beam, guides reflection light from the concave mirror to a wavefront sensor (that is, a Shack-Hartmann wavefront sensor), and thereby analyzes the wavefront of the laser beam (see Japanese Patent Laid-open No. 2021-79394, for example).

However, in a case of using an optical measuring instrument such as the beam profiler or the wavefront sensor, a need arises for the concave mirror for reflecting the laser beam, an optical system dedicated to observation for guiding the reflection light reflected by the concave mirror to the above-described optical measuring instrument, and the optical measuring instrument itself. Thus, the laser processing apparatus becomes correspondingly more expensive.

In addition, because a part of the laser beam is branched to the concave mirror, and the rest of the laser beam is branched to a condenser including a condensing lens, precise position adjustment is necessary for the condenser, the optical system dedicated to observation, and the optical measuring instrument. If the position adjustment is not made properly, the astigmatism cannot be evaluated properly.

### SUMMARY OF THE INVENTION

The present invention has been made in view of such problems. It is an object of the present invention to evaluate the astigmatism of a laser beam in a laser processing apparatus without using any of a concave mirror disposed in the vicinity of a chuck table, an optical measuring instrument such as a beam profiler or a wavefront sensor, and an optical system which is dedicated to observation and is disposed between the concave mirror and the optical measuring instrument.

In accordance with an aspect of the present invention, there is provided an evaluating method for evaluating astigmatism of a laser beam in a laser processing apparatus, the evaluating method including a processing step of forming a plurality of processing traces each having a spot shape by irradiating different positions of an exposed surface of a workpiece with the laser beam according to respective height positions of a condensing point of the laser beam by positioning the condensing point at a plurality of the height positions located between a first height position separated from a reference height position where the condensing point of the laser beam is located at the exposed surface of the workpiece by a predetermined distance in one direction of a first direction as a direction of irradiation of the workpiece with the laser beam and a second height position separated from the reference height position by a predetermined distance in another direction opposite from the one direction in the first direction, and moving a condenser of a laser beam irradiating unit and the workpiece relative to each other along a second direction intersecting the first direction, the condensing point being positioned at the plurality of height positions by moving the condenser and the workpiece relative to each other along the first direction, an imaging step of obtaining an image of each of the processing traces by imaging the plurality of processing traces, an aspect ratio calculating step of calculating an aspect ratio of each of the processing traces from the image of each of the processing traces, and an astigmatism calculating step of calculating an index indicating a degree of the astigmatism on the basis of the plurality of height positions of the condensing point and the aspect ratio of each of the processing traces.

In accordance with another aspect of the present invention, there is provided a laser processing apparatus including a holding unit configured to hold a workpiece, a laser beam irradiating unit including a laser oscillator and a condenser for condensing a laser beam emitted from the laser oscillator, a first moving mechanism configured to move the condenser and the holding unit relative to each other along a first direction as a direction of irradiation of the workpiece with the laser beam, a second moving mechanism configured to move the condenser and the holding unit relative to each other along a second direction intersecting the first direction, an imaging unit configured to image the workpiece held by the holding unit, and a controller including a processor and a memory. The controller includes a processing control section configured to form a plurality of processing traces each having a spot shape by irradiating different positions of an exposed surface of the workpiece with the laser beam according to respective height positions of a condensing point of the laser beam by positioning the condensing point at a plurality of the height positions located between a first height position separated from a reference height position where the condensing point is located at the exposed surface of the workpiece by a predetermined distance in one direction of the first direction and a second height position separated from the reference height position by a predetermined distance in another direction opposite from the one direction in the first direction, and moving the condenser and the workpiece relative to each other along the second direction by operating the second moving mechanism, the condensing point being positioned at the plurality of height positions by moving the condenser and the workpiece relative to each other along the first direction by operating the first moving mechanism, an aspect ratio calculating section configured to calculate an aspect ratio of each of the processing traces from an image of each of the plurality of processing traces imaged by the imaging unit, and an astigmatism calculating section configured to calculate an index indicating a degree of astigmatism on the basis of the plurality of height positions of the condensing point and the aspect ratio of each of the processing traces.

Preferably, the laser beam irradiating unit further includes an astigmatism correcting unit configured to correct the astigmatism, and the controller further includes an astigmatism correcting section configured to, when an absolute value of the index calculated by the astigmatism calculating section and indicating the degree of the astigmatism is larger than a threshold value, make the absolute value of the index equal to or less than the threshold value by operating the astigmatism correcting unit.

In addition, preferably, the astigmatism correcting unit includes a spatial light phase modulator or a pair of convex cylindrical lenses.

The evaluating method according to one aspect of the present invention forms a plurality of processing traces each having a spot shape on the workpiece (processing step), obtains an image of each of the processing traces by imaging the plurality of processing traces (imaging step), calculates the aspect ratio of each of the processing traces from the image of each of the processing traces (aspect ratio calculating step), and calculates an index indicating a degree of astigmatism from a plurality of height positions of the condensing point and the aspect ratio of each of the processing traces (astigmatism calculating step). Hence, the astigmatism of the laser beam can be evaluated in the laser processing apparatus without the use of a concave mirror disposed in the vicinity of a chuck table, an optical measuring instrument such as a beam profiler or a wavefront sensor, and an optical system which is dedicated to observation and is disposed between the concave mirror and the optical measuring instrument. This can lead to a reduction in cost of the laser processing apparatus, and obviates a need for precise position adjustment work for the concave mirror, the optical measuring instrument, and the optical system dedicated to observation because the concave mirror, the optical measuring instrument, and the optical system are omitted.

In the laser processing apparatus according to another aspect of the present invention, the imaging unit images the plurality of processing traces each having a spot shape, then the aspect ratio calculating section of the controller calculates the aspect ratio of each of the processing traces from an image of each of the plurality of processing traces, and the astigmatism calculating section of the controller calculates the index indicating the degree of astigmatism from the plurality of height positions of the condensing point and the aspect ratio of each of the processing traces. Hence, the astigmatism of the laser beam can be evaluated in the laser processing apparatus without the use of the concave mirror, the optical measuring instrument, and the optical system dedicated to observation described above. This can lead to a reduction in cost of the laser processing apparatus, and obviates a need for precise position adjustment work for the concave mirror, the optical measuring instrument, and the optical system dedicated to observation.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a flowchart of an evaluating method;

FIG. 2 is a perspective view of a laser processing apparatus;

FIG. 3A is a schematic diagram of a laser beam irradiating unit;

FIG. 3B is a perspective view of a pair of cylindrical lenses;

FIG. 4A is a diagram illustrating a condensed state of an ideal laser beam not having astigmatism;

FIG. 4B is a diagram illustrating a condensed state of a laser beam having astigmatism;

FIG. 5 is a diagram illustrating a holding step and a processing step;

FIG. 6A is a diagram illustrating a condensing point located at a reference height position;

FIG. 6B is a diagram illustrating the condensing point located above the reference height position;

FIG. 6C is a diagram illustrating the condensing point located below the reference height position;

FIG. 7A is a diagram illustrating an example of a processing trace as viewed in plan;

FIG. 7B is a diagram illustrating another example of the processing trace as viewed in plan;

FIG. 8 is a graph illustrating a result of measurement of a defocus value and ellipticity as well as an approximate curve based on the measurement result;

FIG. 9A is a diagram illustrating a cross section of a laser beam in an XY coordinate system;

FIG. 9B is a diagram illustrating the cross section of the laser beam in an X′Y′ coordinate system;

FIG. 10 is a diagram illustrating an imaging step;

FIG. 11A is a schematic diagram illustrating a measurement of the astigmatism of the laser beam by using a wavefront sensor;

FIG. 11B is a diagram two-dimensionally illustrating the wavefront of the laser beam obtained by using the wavefront sensor;

FIG. 12 is a plan view illustrating an outline of an experiment apparatus that adjusts an amount of change in a distance between the pair of cylindrical lenses and an index indicating a degree of astigmatism;

FIG. 13 is an experiment result illustrating amounts of change in the distance between the pair of cylindrical lenses and the index indicating the degree of astigmatism;

FIG. 14A is a diagram illustrating the aspect ratio of a processing trace according to a first modification;

FIG. 14B is a diagram illustrating the aspect ratio of a processing trace according to a second modification;

FIG. 14C is a diagram illustrating the aspect ratio of a processing trace according to a third modification;

FIG. 15A is a side view illustrating a Z-axis direction moving mechanism according to a second embodiment;

FIG. 15B is a side view illustrating a Z-axis direction moving mechanism according to a third embodiment; and

FIG. 16 is a schematic diagram illustrating a laser beam irradiating unit and a chuck table according to a fourth embodiment.

### DETAILED DESCRIPTION OF THE PREFERRED EMBODIMENTS

### First Embodiment

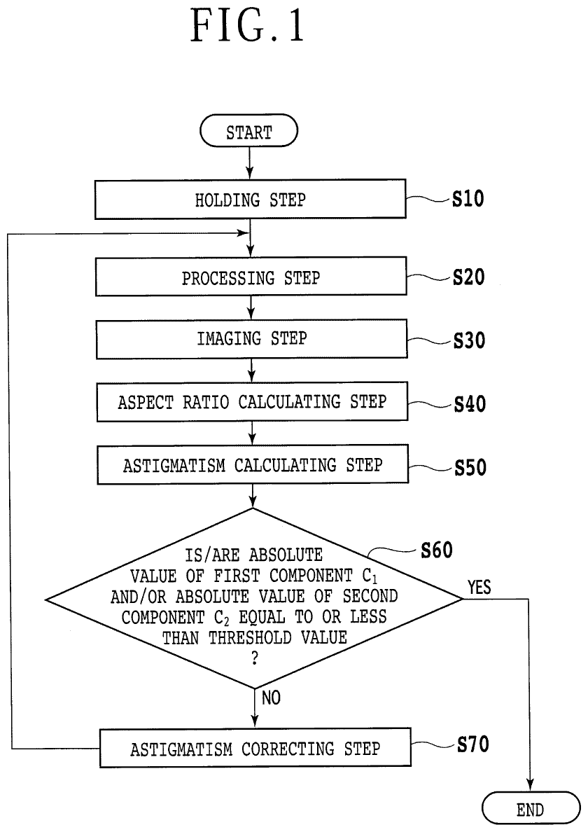

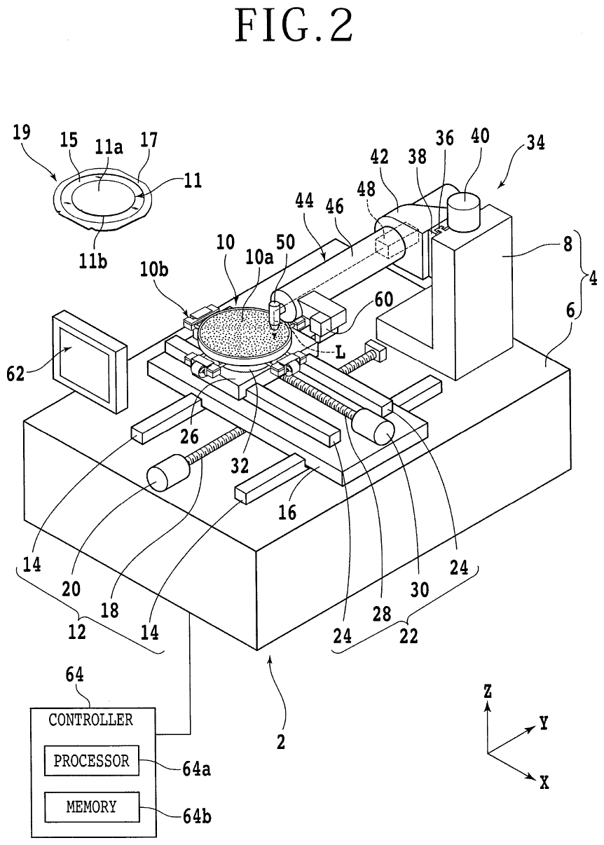

An embodiment according to one aspect of the present invention will be described with reference to the accompanying drawings. FIG. 1 is a flowchart of an evaluating method for evaluating the astigmatism of a laser beam L in a laser processing apparatus 2 illustrated in FIG. 2. The evaluating method sequentially performs a holding step S10, a processing step S20, an imaging step S30, an aspect ratio calculating step S40, an astigmatism calculating step S50, and the like in the laser processing apparatus 2. Accordingly, the laser processing apparatus 2 will first be described. FIG. 2 is a perspective view of the laser processing apparatus 2.

In FIG. 2, a part of constituent elements of the laser processing apparatus 2 are represented by functional blocks. An X-axis direction (second direction), a Y-axis direction, and a Z-axis direction (first direction) each illustrated in FIG. 2 are orthogonal (intersect) to each other. The X-axis direction is substantially parallel with a processing feed direction. The Y-axis direction is substantially parallel with an indexing feed direction. In addition, the Z-axis direction is substantially parallel with a height direction (vertical direction).

The laser processing apparatus 2 includes a base 4 that supports the constituent elements of the laser processing apparatus 2. The base 4 includes a base portion 6 in a flat plate shape and an erected portion 8 that is located in the rear (one direction of the Y-axis direction) of the base portion 6 and extends upward. A chuck table (holding unit) 10 that holds a workpiece 11 under suction is provided above the base portion 6.

The chuck table 10 has a disk-shaped frame body formed of metal. A disk-shaped recessed portion having a smaller diameter than the frame body is formed in an upper portion of the frame body. A disk-shaped porous plate formed of a porous ceramic is fixed to the recessed portion.

A predetermined flow passage (not illustrated) for supplying a negative pressure to the porous plate is formed in the frame body. A suction source (not illustrated) such as a vacuum pump is connected to the frame body via a tube portion (not illustrated). The negative pressure is transmitted from the suction source to the porous plate via the predetermined flow passage.

The upper surface of the porous plate and the upper surface of the frame body are substantially flush with each other, and function as a substantially flat holding surface 10a that holds the workpiece 11 under suction. In the chuck table 10 according to the present embodiment, a vacuum chuck, which holds the workpiece 11 under suction by a negative pressure, is adopted. However, an electrostatic chuck, which holds the workpiece 11 under suction by an electrostatic force, or the like may be adopted.

The holding surface 10a is a substantially flat surface disposed so as to be substantially parallel with an XY plane, and is orthogonal to the Z-axis direction. In a peripheral portion of the frame body, a plurality of clamp units 10b (four clamp units 10b in the present embodiment) are arranged at substantially equal intervals along the circumferential direction of the frame body.

A ball screw type Y-axis direction moving mechanism 12 for moving the chuck table 10 along the Y-axis direction is provided below the chuck table 10. The Y-axis direction moving mechanism 12 includes a pair of Y-axis guide rails 14 fixed to the upper surface of the base portion 6 and arranged so as to be substantially parallel with the Y-axis direction.

A Y-axis direction moving table 16 is slidably fixed to the Y-axis guide rails 14. The lower surface side of the Y-axis direction moving table 16 is provided with a nut portion (not illustrated). A threaded shaft 18 disposed so as to be substantially parallel with the Y-axis direction is rotatably coupled to the nut portion via a plurality of balls (not illustrated).

A driving source 20 such as a stepping motor is connected to one end portion of the threaded shaft 18. When the threaded shaft 18 is rotated by the driving source 20, the Y-axis direction moving table 16 moves along the Y-axis direction. The upper surface side of the Y-axis direction moving table 16 is provided with a ball screw type X-axis direction moving mechanism (second moving mechanism) 22 for moving the chuck table 10 in the X-axis direction.

The X-axis direction moving mechanism 22 includes a pair of X-axis guide rails 24 fixed to the upper surface of the Y-axis direction moving table 16 and arranged so as to be substantially parallel with the X-axis direction. An X-axis direction moving table 26 is slidably fixed to the X-axis guide rails 24.

The lower surface side of the X-axis direction moving table 26 is provided with a nut portion (not illustrated). A threaded shaft 28 disposed so as to be substantially parallel with the X-axis direction is rotatably coupled to the nut portion. A driving source 30 such as a stepping motor is connected to one end portion of the threaded shaft 28.

When the threaded shaft 28 is rotated by the driving source 30, the X-axis direction moving table 26 moves along the X-axis direction. The upper surface side of the X-axis direction moving table 26 is provided with a support base 32 in a cylindrical shape. The chuck table 10 is disposed on an upper portion of the support base 32. A driving source (not illustrated) such as a motor is provided within the support base 32. The driving source rotationally moves the chuck table 10 in a predetermined angle range about a rotational axis parallel with the Z-axis direction as necessary. The chuck table 10 holds the workpiece 11 as described above.

The workpiece 11 is, for example, a wafer including a silicon single crystal substrate. The workpiece 11 is typically a bare wafer on which no devices or the like are formed. However, the workpiece 11 may be a wafer obtained by forming devices, circuits, thin films, or the like on the bare wafer.

The workpiece 11 is not limited to the silicon single crystal substrate, but may be a wafer including a compound semiconductor single crystal substrate, a double oxide single crystal substrate, a ceramic single crystal substrate, or a non-single crystal substrate such as a hard resin.

The workpiece 11 is supported by an annular frame 17 made of metal via a tape 15 made of resin.

Specifically, the workpiece 11 is disposed in an opening portion of the annular frame 17, and then the tape 15 in a circular shape is affixed to an undersurface 11b of the workpiece 11 and one surface of the annular frame 17. A workpiece unit 19 in which the workpiece 11, the tape 15, and the annular frame 17 are integrated with each other is thereby formed. Incidentally, the tape 15 is a dicing tape having a laminated structure of a base material layer and an adhesive layer.

When the undersurface 11b side of the workpiece 11 is held under suction by the holding surface 10a via the tape 15, a top surface (exposed surface) 11a of the workpiece 11 is exposed upward. At this time, the annular frame 17 is sandwiched by the above-described plurality of clamp units 10b.

The erected portion 8 is provided with a Z-axis direction moving mechanism (first moving mechanism) 34. The Z-axis direction moving mechanism 34 includes a pair of Z-axis guide rails 36 fixed to the erected portion 8. Incidentally, FIG. 2 illustrates one Z-axis guide rail 36.

A Z-axis direction moving plate 38 is slidably attached to the pair of Z-axis guide rails 36. The undersurface side of the Z-axis direction moving plate 38 is provided with a nut portion (not illustrated). A threaded shaft (not illustrated) disposed so as to be substantially parallel with the Z-axis direction is rotatably coupled to the nut portion via a plurality of balls (not illustrated).

A driving source 40 such as a stepping motor is connected to an upper end portion of the threaded shaft. When the threaded shaft is rotated by the driving source 40, the Z-axis direction moving plate 38 moves along the Z-axis direction. A support 42 is fixed to the top surface side of the Z-axis direction moving plate 38.

The support 42 supports a cylindrical casing 46 that constitutes a laser beam irradiating unit 44. In the present embodiment, a laser oscillator 48 is disposed within the casing 46. However, the laser oscillator 48 may be disposed outside the casing 46. In this case, the laser oscillator 48 does not move together with the casing 46 along the Z-axis direction.

The laser oscillator 48 includes a laser medium such as a Nd:YAG crystal. The laser oscillator 48 further includes an excitation light source such as a lamp for irradiating the laser medium with excitation light and a Q-switch for controlling timing in which the laser beam L is emitted. A pulsed laser beam L having a predetermined wavelength is emitted from the laser oscillator 48.

In the present embodiment in which laser ablation processing is performed on the workpiece 11, the laser beam L is emitted from the laser oscillator 48, and is thereafter converted by a nonlinear optical crystal (not illustrated) into a predetermined wavelength capable of processing the workpiece 11. Further, the laser beam L is thereafter applied from a head unit 50 to the holding surface 10a along the Z-axis direction. That is, the Z-axis direction is a direction of irradiation of the workpiece 11 with the laser beam L.

The nonlinear optical crystal is an LBO (LiB₃O₅) crystal, for example. The nonlinear optical crystal converts the wavelength of the laser beam L from 1064 nm (wavelength transmitted through the workpiece 11) to 355 nm (wavelength absorbed by the workpiece 11). The wavelength-converted pulsed laser beam L is applied from the head unit 50 to the holding surface 10a.

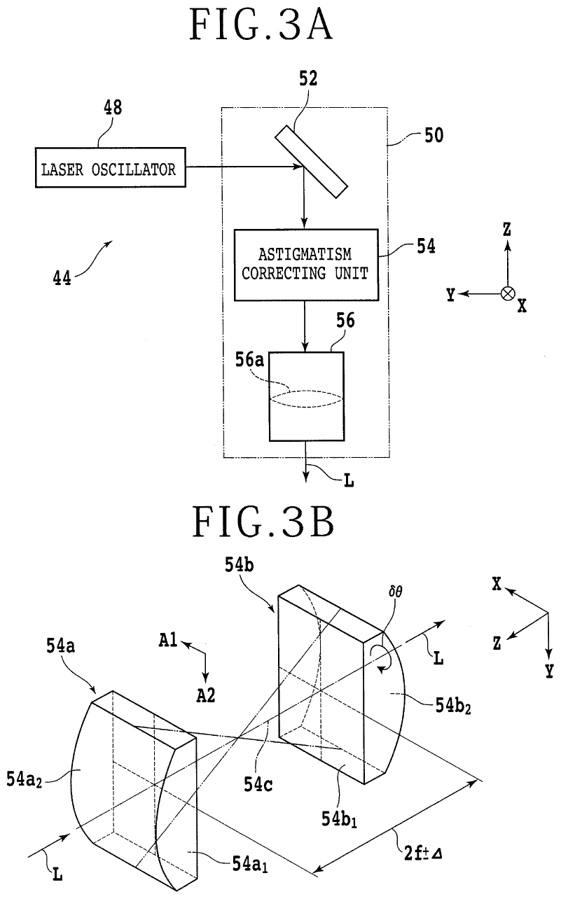

In the following, the laser beam irradiating unit 44 will be further described with reference to FIG. 3A and FIG. 3B. FIG. 3A is a schematic diagram of the laser beam irradiating unit 44. The head unit 50 includes: a mirror 52 that changes the traveling direction of the laser beam L; an astigmatism correcting unit 54 that corrects the astigmatism of the laser beam L; and a condenser 56 for condensing the laser beam L.

The astigmatism correcting unit 54 in the present embodiment includes a pair of plano-convex (that is, convex) cylindrical lenses 54a and 54b illustrated in FIG. 3B. FIG. 3B is a perspective view of the pair of cylindrical lenses 54a and 54b each having substantially a same focal length f. The pair of cylindrical lenses 54a and 54b has rectangular flat surfaces 54a1 and 54b1 that are arranged so as to face each other and are substantially flat. The longitudinal sides of the flat surfaces 54a1 and 54b1 are substantially parallel with each other. The lateral sides of the flat surfaces 54a1 and 54b1 are also substantially parallel with each other.

FIG. 3B illustrates an imaginary axis 54c located at the centers of the flat surfaces 54a1 and 54b1 and orthogonal to the flat surfaces 54a1 and 54b1. The flat surfaces 54a1 and 54b1 substantially completely coincide with each other when the pair of cylindrical lenses 54a and 54b is viewed along the axis 54c.

Incidentally, the flat surfaces 54a1 and 54b1 may have a circular shape rather than a rectangular shape. In this case, the external shape of each of the cylindrical lenses 54a and 54b is a circular shape, and the flat surfaces 54a1 and 54b1 substantially completely coincide with each other when the pair of cylindrical lenses 54a and 54b is viewed along the axis 54c illustrated in FIG. 3B.

As illustrated in FIG. 3B, the pair of cylindrical lenses 54a and 54b is arranged such that a lateral direction A1 in which cylindrical projecting portions of the cylindrical lenses 54a and 54b extend is parallel with the X-axis direction and such that a longitudinal direction A2 orthogonal to the lateral direction A1 in the flat surfaces 54a1 and 54b1 is parallel with the Y-axis direction. However, in a case where the pair of cylindrical lenses 54a and 54b is rotated about the axis 54c, as will be described later, the lateral direction A1 is not necessarily parallel with the X-axis direction. The same is true for the longitudinal direction A2.

The laser beam L passes through the pair of cylindrical lenses 54a and 54b along the axis 54c. That is, the laser beam L is made incident on a convex surface 54a2 of the cylindrical lens 54a, and is then emitted from a convex surface 54b2 of the cylindrical lens 54b.

Now, the laser beam L is ideally constituted by a perfectly flat wavefront orthogonal to the traveling direction of the laser beam L. In actuality, however, the laser beam L has a finite distortion (wavefront aberration). Letting R be the beam radius of the laser beam L, a wavefront aberration W can be expanded as in the following Equation (1) by using a Zernike polynomial: Z^{m}ₙ as an orthogonal function. Incidentally, x and y are coordinate axes defining a plane orthogonal to the traveling direction of the laser beam L, and c^{m}ₙ is a coefficient corresponding to (m, n) of the Zernike polynomial Z^{m}ₙ.

$$\begin{matrix}[ Math . 1 ] & \\ W ( x , y ) = {\sum }_{n , m} {c}_{n}^{m} {Z}_{n}^{m} ( \frac{x}{R} , \frac{y}{R} ) & ( 1 )\end{matrix}$$

Details of the Zernike polynomial are described in “Journal of Modern Optics,” Vol. 58, No. 7, Taylor & Francis, 10 Apr. 2011, p. 545-561 by Vasudevan Lakshminarayanan and Andre Fleck, for example.

In Equation (1), c²₂Z²₂ corresponds to an astigmatism component in a 0°-90° direction, and c⁻²₂Z⁻²₂ corresponds to an astigmatism component in a ±45° direction. Here, Z²₂ is expressed by the following Equation (2), and Z⁻²₂ is expressed by the following Equation (3).

$$\begin{matrix}[ Math . 2 ] & \\ {Z}_{2}^{2} = - {( \frac{x}{R} )}^{2} + {( \frac{y}{R} )}^{2} & ( 2 )\end{matrix}$$

$$\begin{matrix}[ Math . 3 ] & \\ {Z}_{2}^{- 2} = \frac{2 xy}{{R}^{2}} & ( 3 )\end{matrix}$$

Thus, by expanding the wavefront by the Zernike polynomial, it is possible to express the astigmatism component in the 0°-90° direction by c²₂ and express the astigmatism component in the +45° direction by c⁻²₂. In the following, for simplicity, c²₂ will be denoted as a first component c₁, and c⁻²₂ will be denoted as a second component c₂.

Here, when a distance between the pair of cylindrical lenses 54a and 54b is changed by Δ from 2f by moving one or both of the pair of cylindrical lenses 54a and 54b along a direction parallel with the axis 54c, δc₁ as an amount of change in the first component c₁ is expressed by using the following Equation (4).

$$\begin{matrix}[ Math . 4 ] & \\ Δ = \frac{4 {f}^{2} δ {c}_{1}}{{R}^{2}} & ( 4 )\end{matrix}$$

In addition, when one of the cylindrical lenses 54a and 54b is rotated about the axis 54c while the distance between the pair of cylindrical lenses 54a and 54b is maintained, δc₂ as an amount of change in the second component c₂ is expressed by using the following Equation (5).

$$\begin{matrix}[ Math . 5 ] & \\ δ θ = \frac{2 f δ {c}_{2}}{{R}^{2}} & ( 5 )\end{matrix}$$

Incidentally, R used in Equations (4) and (5) is the radius of the laser beam L before entering the astigmatism correcting unit 54. It is preferable that, in a case where the laser beam L immediately after being emitted from the laser oscillator 48 is a Gaussian beam, the width of the laser beam L when the power per unit area of the laser beam L is 1/e² of a peak power (e is the base of a natural logarithm) be defined as the diameter of the laser beam L and half of the diameter of the laser beam L be defined as R described above.

The present embodiment uses the pair of plano-convex cylindrical lenses 54a and 54b, and therefore has an advantage of being able to adjust the first component c₁ and the second component c₂ without enlarging or reducing the diameter of the laser beam L as compared with a case where a plano-convex cylindrical lens (not illustrated) and a plano-concave cylindrical lens (not illustrated) are arranged so as to face each other in a state in which a concave portion and a convex portion of the cylindrical lenses are separated from each other.

Incidentally, the astigmatism correcting unit 54 may include an LCOS-SLM (Liquid Crystal on Silicon-Spatial Light Modulator) (that is, a spatial light phase modulator) in place of the pair of cylindrical lenses 54a and 54b. The LCOS-SLM can control the phase of the laser beam L incident on the LCOS-SLM so as to cancel out astigmatism by electrically controlling the inclination of liquid crystal molecules appropriately. That is, the LCOS-SLM can adjust both the first component c₁ and the second component c₂.

The laser beam L enters the condenser 56 after passing through the astigmatism correcting unit 54. The condenser 56 includes a condensing lens 56a. The condenser 56 condenses the laser beam L in the vicinity of the top surface 11a of the workpiece 11 held by the holding surface 10a.

The position in the Z-axis direction of a condensing point of the laser beam L is adjusted with respect to the workpiece 11 by moving the condenser 56 along the Z-axis direction by the Z-axis direction moving mechanism 34. That is, the position in the Z-axis direction of the condensing point is adjusted by moving the condenser 56 and the chuck table 10 relative to each other along the Z-axis direction.

In addition, a position irradiated with the laser beam L in the workpiece 11 is adjusted by moving the condenser 56 and the chuck table 10 holding the workpiece 11 relative to each other along the X-axis direction by the X-axis direction moving mechanism 22.

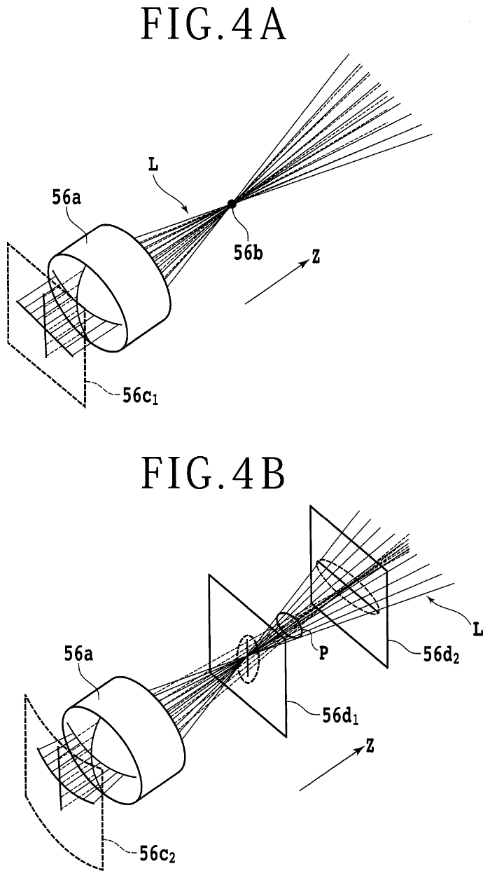

FIG. 4A is a diagram illustrating a state in which an ideal laser beam L that does not have astigmatism is passed through the condensing lens 56a and is condensed at a focal point 56b. A wavefront 56c1 of the laser beam L illustrated in FIG. 4A is substantially parallel with the XY plane before entering the condensing lens 56a. In this case, at the focal point 56b of the condensing lens 56a located forward of the condensing lens 56a in the traveling direction of the laser beam L, the laser beam L is condensed such that an irradiated region in a plane orthogonal to the traveling direction is a substantially perfect circle.

On the other hand, FIG. 4B is a diagram illustrating a state in which a laser beam L having astigmatism is condensed after passing through the condensing lens 56a. A wavefront 56c2 of the laser beam L illustrated in FIG. 4B is not parallel with the XY plane, but is in a saddle shape. In this case, at a first plane 56d1 located forward of the condensing lens 56a in the traveling direction of the laser beam L and orthogonal to the traveling direction, the laser beam L is condensed so as to form an ellipse whose major axis is disposed along a first direction orthogonal to the traveling direction.

Further, at a second plane 56d₂ located forward of the first plane 56d₁ in the traveling direction of the laser beam L and orthogonal to the traveling direction, the laser beam L is condensed so as to form an ellipse whose major axis is disposed along a second direction orthogonal to each of the traveling direction and the first direction. Incidentally, between the first plane 56d₁ and the second plane 56d₂ in the traveling direction of the laser beam L, the laser beam L is condensed such that the spot of the laser beam L in a plane orthogonal to the traveling direction is a substantially perfect circle. In the present embodiment, a position at which the spot of the laser beam L in the plane orthogonal to the traveling direction of the laser beam L becomes a substantially perfect circle will be referred to as a condensing point P of the laser beam L.

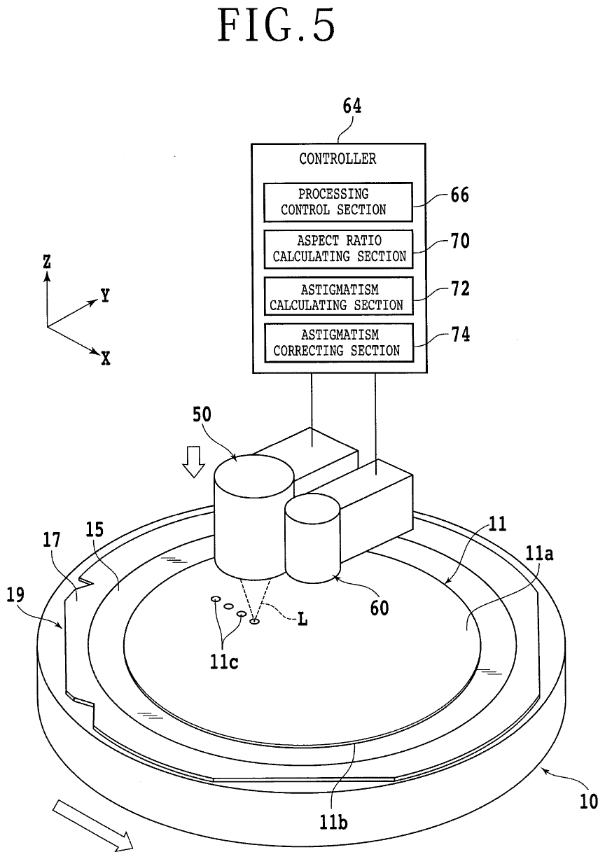

As illustrated in FIG. 4B, the shape of the spot of the laser beam L changes according to the position in the traveling direction of the laser beam L (that is, the Z-axis direction). Thus, the shape of a region irradiated with the laser beam L applied to the top surface 11a differs according to the position of the condensing point P in the Z-axis direction. Accordingly, as will be described later, the present embodiment evaluates a degree of astigmatism of the laser beam L by using the shapes of processing traces 11c (see FIG. 5) formed by irradiating the workpiece 11 with the laser beam L to perform ablation processing.

Here, the description returns to FIG. 2. An imaging unit 60 is provided to a side portion in the vicinity of a distal end portion of the cylindrical casing 46. The imaging unit 60 in the present embodiment is a microscope camera unit. The imaging unit 60 includes an objective lens, a light source, and an imaging element, none of which is illustrated. For example, the light source includes a white light emitting diode (LED) capable of emitting light in a visible light range, and the imaging element includes a charge-coupled device (CCD) image sensor or a complementary metal-oxide-semiconductor (CMOS) image sensor.

The objective lens is disposed so as to face the holding surface 10a of the chuck table 10. The imaging unit 60 can image the top surface 11a side of the workpiece 11 held by the holding surface 10a. The laser beam L does not directly or indirectly enter the imaging unit 60. The imaging unit 60 is used for checking a processing position at which processing is to be performed on the workpiece 11 before the processing of the workpiece 11, checking a result of the processing performed on the workpiece 11 after the processing of the workpiece 11, and the like.

Now, the base 4 is provided with a cover (not illustrated) that covers the constituent elements of the laser processing apparatus 2. A side surface of the front (another direction of the Y-axis direction) of the cover is provided with a touch panel 62. The touch panel 62 is a liquid crystal display including a capacitive type touch sensor. The touch panel 62 functions as an input apparatus for a worker to input an instruction to the laser processing apparatus 2, and further functions also as a display apparatus for displaying a graphical user interface (GUI) for inputting an instruction and an image obtained by the imaging unit 60 or the like.

The laser processing apparatus 2 is provided with a controller 64 that controls the operations of the Y-axis direction moving mechanism 12, the X-axis direction moving mechanism 22, the driving source within the support base 32, the Z-axis direction moving mechanism 34, the suction source, the laser beam irradiating unit 44, the imaging unit 60, the touch panel 62, and the like. The controller 64 is, for example, constituted by a computer including a processor 64a typified by a central processing unit (CPU) and a memory 64b. The memory 64b includes a main storage apparatus such as a dynamic random access memory (DRAM) and an auxiliary storage apparatus such as a flash memory.

The auxiliary storage apparatus stores software including predetermined programs. Functions of the controller 64 are implemented by operating the processor 64a and the like according to the software. The auxiliary storage apparatus stores a first program. When the first program is executed by the processor 64a, the first program functions as a processing control section 66 that forms a plurality of processing traces 11c on the workpiece 11 by operating the laser beam irradiating unit 44, the Y-axis direction moving mechanism 12, the X-axis direction moving mechanism 22, the Z-axis direction moving mechanism 34, and the like (see FIG. 5).

The processing control section 66 in the present embodiment operates the X-axis direction moving mechanism 22 to thereby move the condenser 56 and the chuck table 10 relative to each other along the X-axis direction, and operates the Z-axis direction moving mechanism 34 so as to position the condensing point P at a plurality of height positions along the Z-axis direction.

However, the processing control section 66 may operate the Y-axis direction moving mechanism 12 to thereby move the condenser 56 and the chuck table 10 relative to each other along the Y-axis direction, and operate the Z-axis direction moving mechanism 34 so as to position the condensing point P at the plurality of height positions along the Z-axis direction.

In addition, the processing control section 66 may operate the X-axis direction moving mechanism 22 and the Y-axis direction moving mechanism 12 to thereby move the condenser 56 and the chuck table 10 relative to each other along the X-axis direction and the Y-axis direction, and operate the Z-axis direction moving mechanism 34 so as to position the condensing point P at the plurality of height positions along the Z-axis direction.

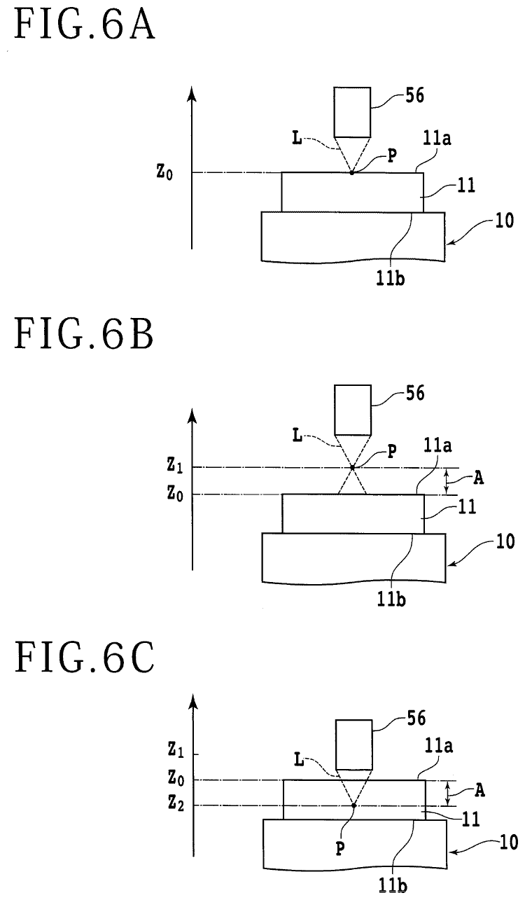

The plurality of height positions are located between a first height position Z₁ (see FIG. 6B) separated from a reference height position Z₀ (see FIG. 6A) in an upward direction (one direction of the Z-axis direction) by a predetermined distance A and a second height position Z₂ (see FIG. 6C) separated from the reference height position Z₀ in a downward direction (another direction opposite from the one direction) in the Z-axis direction by the predetermined distance A.

Incidentally, suppose in the present specification that the plurality of height positions being located between the first height position Z₁ and the second height position Z₂ means that each of the first height position Z₁ and the second height position Z₂ located at end portions in the Z-axis direction is included in the plurality of height positions.

FIG. 6A is a diagram illustrating the condensing point P located at the reference height position Z₀. FIG. 6B is a diagram illustrating the condensing point P located above the reference height position Z₀. FIG. 6C is a diagram illustrating the condensing point P located below the reference height position Z₀.

The reference height position Z₀ is the height position in the Z-axis direction of the top surface 11a of the workpiece 11 held by the holding surface 10a. When the condensing point P is located at the top surface 11a (that is, the reference height position Z₀), the laser beam L is just focused on the top surface 11a.

When the condensing point P is located at other than the top surface 11a (that is, the reference height position Z₀) between the first height position Z₁ and the second height position Z₂ in the Z-axis direction, on the other hand, the laser beam L is defocused from the top surface 11a. The predetermined distance A that defines the first height position Z₁ and the second height position Z₂ is 700 μm, for example, but is not limited to only 700 μm.

The processing control section 66 applies the laser beam L from the condenser 56 to the top surface 11a in timings in which the condensing point P is disposed at the plurality of height positions between the first height position Z₁ and the second height position Z₂ by moving the condenser 56 and the workpiece 11 held by the chuck table 10 relative to each other along the Z-axis direction.

For example, the processing control section 66 controls application and non-application of the laser beam L from the condenser 56 by electrically controlling an acousto-optic modulator (AOM) or an electro-optic modulator (EOM) (neither is illustrated) that is disposed between the laser oscillator 48 and the mirror 52 (see FIG. 3A) and functions as a shutter. In this case, the chuck table 10 is moved along the X-axis direction at a predetermined speed, the condenser 56 is moved along the Z-axis direction at a predetermined speed from the first height position Z₁ to the second height position Z₂, and the shutter is opened at fixed time intervals.

Thus positioning the condensing point P at the plurality of height positions and moving the condensing point P and the workpiece 11 relative to each other along the X-axis direction causes different positions of the top surface 11a to be discretely irradiated with the laser beam L according to the respective height positions of the condensing point P. Consequently, processing traces 11c in a spot shape are each formed.

Incidentally, the processing control section 66 may set the repetition frequency of the laser beam L at a sufficiently low value by controlling the Q-switch in place of the shutter such as the AOM or the EOM. For example, when the repetition frequency of the laser beam L is set at 20 Hz, the laser beam L is applied from the condenser 56 at a frequency of once in 0.05 s.

In this case, when the chuck table 10 is moved at 600 mm/s, 10 processing traces 11c arranged at substantially equal intervals can be formed in a range of 300 mm (that is, in a time period of 0.5 s) along the X-axis direction. That is, the processing traces 11c can be formed at different positions of the top surface 11a according to the repetition frequency of the laser beam L and the relative moving speed of the condensing point P and the chuck table 10 in the X-axis direction in place of the turning on and off of the laser beam L by the AOM, the EOM, or the like.

After the plurality of processing traces 11c are formed on the top surface 11a, images of the plurality of processing traces 11c are imaged by the imaging unit 60. The imaging unit 60 in the present embodiment individually images each of the processing traces 11c. However, in a case where the imaging unit 60 has a sufficiently high performance, the plurality of processing traces 11c may be collectively imaged en bloc.

The auxiliary storage apparatus stores a second program. By executing the second program by the processor 64a, the second program functions as an aspect ratio calculating section 70 (see FIG. 5). The aspect ratio calculating section 70 subjects respective images of the plurality of processing traces 11c to image processing, and thereby calculates an aspect ratio ε of each of the processing traces 11c and an inclination angle θ of the processing trace 11c from each of the images. In the present embodiment in which the processing traces 11c are elliptic, the aspect ratio ε is calculated on the basis of a ratio between the lengths of two axes orthogonal to each other.

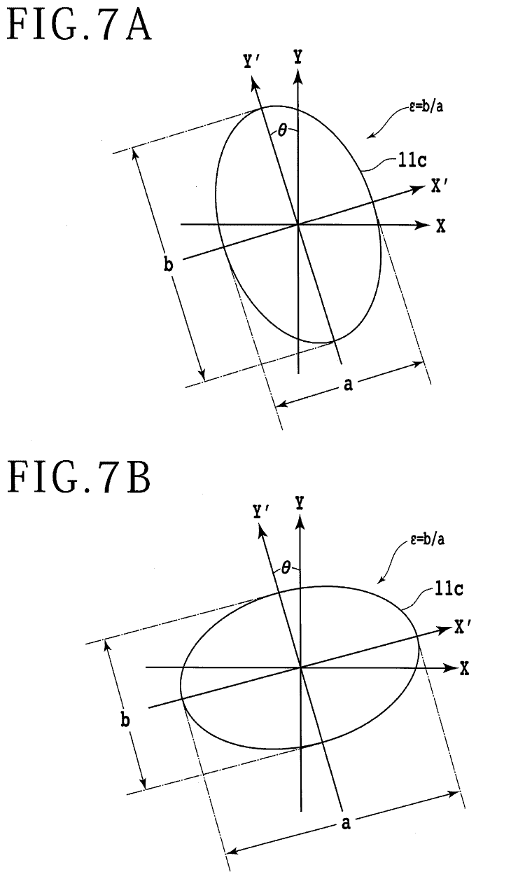

FIG. 7A is a diagram illustrating an example of a processing trace 11c as viewed in plan. In the present example, the processing trace 11c has an elliptic shape, the minor axis of the processing trace 11c is along an X′-axis direction, and the length of the minor axis is a. In addition, the major axis of the processing trace 11c is along a Y′-axis direction, and the length of the major axis is b. The X′-axis direction and the Y′-axis direction are orthogonal to each other, and the X′-axis direction is inclined with respect to the X-axis direction by an angle θ in the XY plane.

As will be described later, the present embodiment calculates the inclination angle θ formed between the X′-axis direction and the X-axis direction. In addition, the aspect ratio ε of the processing trace 11c is calculated on the basis of {(Length of Processing Trace 11c along Y′-axis Direction)/(Length of Processing Trace 11c along X′-axis Direction)}. In the example of FIG. 7A, the aspect ratio ε of the processing trace 11c is b/a.

FIG. 7B is a diagram illustrating another example of the processing trace 11c as viewed in plan. In the example of FIG. 7B, the major axis of the processing trace 11c which major axis has the length a is along the X′-axis direction, and the minor axis of the processing trace 11c which minor axis has the length b is along the Y′-axis direction. Also in the example of FIG. 7B, the aspect ratio ε of the processing trace 11c is b/a.

It is to be noted that the above-described calculating method that sets the length along the X′-axis direction as a denominator and sets the length along the Y′-axis direction as a numerator in calculating the aspect ratio ε is a mere example. The length along the Y′-axis direction may be set as the denominator, and the length along the X′-axis direction may be set as the numerator.

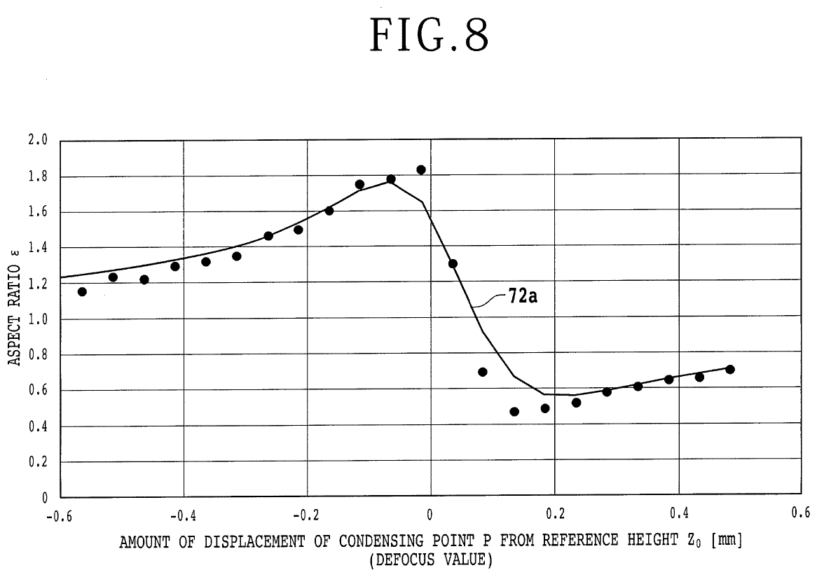

A plurality of dots illustrated in FIG. 8 are obtained when displacements of the plurality of height positions of the condensing point P with respect to the reference height position Z₀ (that is, defocus values) are plotted on an axis of abscissas, and the aspect ratios E of the respective processing traces 11c are plotted on an axis of ordinates.

A defocus value indicates a degree to which the condensing point P of the laser beam L is displaced from the top surface 11a of the workpiece 11 (that is, a degree of defocus). The defocus value is zero when the condensing point P is located at the reference height position Z₀ (that is, at the top surface 11a of the workpiece 11) (see FIG. 6A). In addition, in the present embodiment, the defocus value is assumed to be positive when the condensing point P is located on a side separated from the workpiece 11 more than the reference height position Z₀ as illustrated in FIG. 6B, and the defocus value is assumed to be negative when the condensing point P is located more to the workpiece 11 side than the reference height position Z₀ as illustrated in FIG. 6C.

An approximate curve 72a (see FIG. 8) whose errors with respect to the plurality of dots illustrated in FIG. 8 are minimized by a method of least squares is calculated by an astigmatism calculating section 72 (see FIG. 5) of the controller 64. The auxiliary storage apparatus stores a third program. By executing the third program by the processor 64a, the third program functions as the astigmatism calculating section 72. As will be described later in detail, the aspect ratio ε (see Equation (12)) obtained by a theoretical study in the present embodiment is expressed as a function of the defocus value, and includes the unknown first component c₁ and other known parameters.

The astigmatism calculating section 72 calculates the first component c₁ (or a first component c₁′ to be described later) by comparing the approximate curve 72a calculated by the method of least squares with the theoretical aspect ratio ε including the unknown first component c₁ (or the first component c₁′ to be described later) and expressed as a function of the defocus value.

The astigmatism calculating section 72 in the present embodiment calculates the first component c₁ after calculating the approximate curve 72a by using the method of least squares. However, instead of this, the astigmatism calculating section 72 may calculate the first component c₁ on the basis of the slope of an approximate straight line at a defocus value of zero, relation between a maximal value and a minimal value of the aspect ratio E, and the like. However, the first component c₁ can be calculated with relatively high accuracy when the method of least squares is used.

In the following, description will be made of the aspect ratio ε including the first component c₁ and expressed as a function of the defocus value. First, the radius of an ideal laser beam L not having astigmatism is expressed by using the following Equation (6). Incidentally, the traveling direction of the laser beam L is assumed to be parallel with the Z-axis direction.

$$\begin{matrix}[ Math . 6 ] & \\ w ( {Z}_{DF} ) = \sqrt{{( \frac{{M}^{2} f λ}{π D} )}^{2} + {( \frac{{Dz}_{DF}}{2 f} )}^{2}} & ( 6 )\end{matrix}$$

In Equation (6), ZDF is the defocus value. M² is a numerical value indicating a deviation from an ideal Gaussian laser beam (fundamental mode beam). M²=1 in a case of the ideal Gaussian laser beam. f is the focal length of the condensing lens 56a. λ is the wavelength of the laser beam L. π is the ratio of the circumference of a circle to the diameter thereof. D is the diameter of the laser beam L before entering the condensing lens 56a, and is substantially equal to twice R illustrated in the above Equations (4) and (5).

Supposing that the astigmatism of the laser beam L is evaluated in the XY plane, the astigmatism can include the first component c₁ described above and the second component c₂ described above. Accordingly, for simplicity, the coordinate system in which the laser beam L is treated is transformed such that the second component c₂ becomes zero. Specifically, the X-axis and the Y-axis are rotated by an angle θ in order to obtain a new X′ coordinate and a new Y′ coordinate such that the second component c₂ is zero (see the following Equation (7)).

$$\begin{matrix}[ Math . 7 ] & \\ ( \begin{matrix}{X}^{′} \\ {Y}^{′}\end{matrix} ) = ( \begin{matrix}cos θ & - sin θ \\ sin θ & cos θ\end{matrix} ) ( \begin{matrix}X \\ Y\end{matrix} ) & ( 7 )\end{matrix}$$

In this case, an X-coordinate and a Y-coordinate including the first component c₁ and the second component c₂, and the X′ coordinate and the Y′ coordinate not including the second component c₂ but including the first component c′ after the transformation of the coordinate system satisfy the following Equation (8) on the basis of Equation (2) and Equation (3).

$$\begin{matrix}[ Math . 8 ] & \\ ( \frac{{c}_{1}}{{R}^{2}} ) ( {Y}^{2} - {X}^{2} ) + ( \frac{{c}_{2}}{{R}^{2}} ) ( 2 XY ) = ( \frac{{c}_{1}^{′}}{{R}^{2}} ) ( {Y}^{′ 2} - {X}^{′ 2} ) & ( 8 )\end{matrix}$$

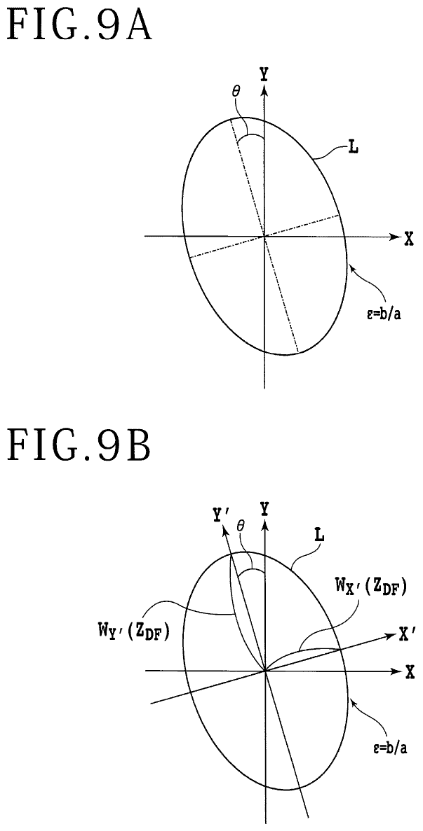

FIG. 9A is a diagram illustrating a cross section of the laser beam L in the XY coordinate system. FIG. 9B is a diagram illustrating the cross section of the laser beam L in the X′Y′ coordinate system. From Equation (7) and Equation (8), the first component c₁ and the second component c₂ are expressed by the following Equation (9) using the first component c₁′.

$$\begin{matrix}[ Math . 9 ] & \\ {c}_{1} = {c}_{1}^{′} cos 2 θ , {c}_{2} = {c}_{1}^{′} sin 2 θ & ( 9 )\end{matrix}$$

Now, in the X′Y′ coordinate system, a length W_{X′} (ZDE) in the X′-axis direction of the laser beam L having the first component c₁′ of astigmatism is expressed by the following Equation (10), and a length W_{Y′} (ZDE) in the Y′-axis direction of the laser beam L having the first component c′ of astigmatism is expressed by the following Equation (11). Incidentally, D_{X′} is the diameter of the laser beam L in the X′-axis direction, and D_{Y′} is the diameter of the laser beam L in the Y′-axis direction.

$$\begin{matrix}[ Math . 10 ] & \\ {w}_{{X}^{′}} ( {z}_{DF} ) = \sqrt{{( \frac{{M}^{2} f λ}{π {D}_{{X}^{′}}} )}^{2} + {[ \frac{{D}_{{X}^{′}}}{2 f} ( {z}_{DF} - \frac{2 {c}_{1}^{′}}{{R}^{2}} ) ]}^{2}} & ( 10 )\end{matrix}$$

$$\begin{matrix}[ Math . 11 ] & \\ {w}_{{Y}^{′}} ( {z}_{DF} ) = \sqrt{{( \frac{{M}^{2} f λ}{π {D}_{{Y}^{′}}} )}^{2} + {[ \frac{{D}_{{Y}^{′}}}{2 f} ( {z}_{DF} - \frac{2 {c}_{1}^{′}}{{R}^{2}} ) ]}^{2}} & ( 11 )\end{matrix}$$

When Equation (10) and Equation (11) are used, the aspect ratio ε (ZDE) of the laser beam L in the X′Y′ coordinate system is expressed by the following Equation (12).

$$\begin{matrix}[ Math . 12 ] & \\ ε ( {Z}_{DF} ) = \frac{{W}_{{Y}^{′}} ( {z}_{DF} )}{{W}_{{X}^{′}} ( {z}_{DF} )} = \frac{\sqrt{{( \frac{{M}^{2} f λ}{π {D}_{{Y}^{′}}} )}^{2} + {[ \frac{{D}_{{Y}^{′}}}{2 f} ( {z}_{DF} + \frac{2 {c}_{1}^{′}}{{R}^{2}} ) ]}^{2}}}{\sqrt{{( \frac{{M}^{2} f λ}{π {D}_{{Y}^{′}}} )}^{2} + {[ \frac{{D}_{{Y}^{′}}}{2 f} ( {z}_{DF} - \frac{2 {c}_{1}^{′}}{{R}^{2}} ) ]}^{2}}} & ( 12 )\end{matrix}$$

Equation (12) merely represents the aspect ratio ε of the laser beam L. However, the aspect ratio ε of the laser beam L can be regarded as the same as the aspect ratio ε (=b/a) of the processing trace 11c described above. This will be described next.

A “processing threshold value” is often adopted as an index illustrating workability of the workpiece 11 in laser processing in which the workpiece 11 is subjected to ablation processing by the laser beam L (see, for example, “Journal of Plasma and Fusion Research,” the Japan Society of Plasma Science and Nuclear Fusion Research Vol. 81, Suppl. (2005) p 195-201 by Masayuki Fujita and Masaki Hashida).

In a case where the laser beam L is applied to the workpiece 11, the workpiece 11 is ablation-processed by the laser beam L only when the laser beam L having a “predetermined light intensity (that is, fluence)” or higher is applied. In addition, the “predetermined light intensity” is substantially constant when a material forming the workpiece 11 as well as the pulse width, wavelength, and repetition frequency of the laser beam L are the same. That is, the “predetermined light intensity” corresponds to the “processing threshold value” described above.

Now, the light intensity of the laser beam L is not uniform when the laser beam L is viewed in a cross section orthogonal to the traveling direction of the laser beam L. The light intensity of the laser beam L tends to be relatively high in a central portion, and tends to be relatively low in a peripheral portion. A distribution of such a light intensity can be expressed by a plurality of contour lines when viewed in the above-described cross section. In the laser beam L emitted from the laser oscillator 48, each of these plurality of contour lines has a substantially similar shape.

These plurality of contour lines include a “first contour line” having a light intensity coinciding with the “processing threshold value” described above. In the ablation processing, only the laser beam L located at the first contour line and on the inside of the first contour line contributes to the laser processing of the workpiece 11. That is, when the workpiece 11 is subjected to the laser processing, the shape of a processing trace that occurs at a time of the laser processing substantially coincides with the shape of the first contour line.

The plurality of contour lines include a “second contour line” representing the external shape of the laser beam L. As described above, each contour line is substantially similar. Thus, the first and second contour lines are substantially similar to each other, and the aspect ratios of the first and second contour lines also substantially coincide with each other.

Hence, it is considered that, when the laser beam L is viewed in a cross section orthogonal to the traveling direction of the laser beam L, the aspect ratio of the external shape of the laser beam L can be regarded as the same as the aspect ratio ε of the processing trace 11c formed on the workpiece 11 by the ablation processing.

Accordingly, the present embodiment adopts a new method of evaluating the aspect ratio ε of the laser beam L before being applied to the workpiece 11 on the basis of the aspect ratio ε of a processing trace 11c formed on the top surface 11a side when the laser beam L is applied to the workpiece 11.

The astigmatism calculating section 72 stores the above Equation (12) in advance. The approximate curve 72a illustrated in FIG. 8 and Equation (12) substantially coincide with each other. Thus, the astigmatism calculating section 72 can calculate the value of the first component c₁′ on the basis of the plurality of height positions of the condensing point P and the aspect ratio ε of each processing trace 11c (that is, on the basis of the approximate curve 72a).

In addition, the astigmatism calculating section 72 stores the above Equation (9) in advance. The astigmatism calculating section 72 calculates the value of the first component c₁ and the value of the second component c₂ (that is, an index indicating a degree of astigmatism) on the basis of the obtained value of the first component c₁′, the value of the angle θ, and Equation (9).

Incidentally, as the index indicating the degree of astigmatism, an astigmatic difference indicating a distance between the condensing point within an X′Z plane and the condensing point within a Y′Z plane may be calculated in addition to the values of the first component c₁ and the second component c₂ as in the present embodiment.

Instead of this, as the index indicating the degree of astigmatism, coefficients of a Zernike polynomial including a normalization coefficient different from the present embodiment (see Z₅ and Z₆ in TABLE I. of ‘R. Noll, “Zernike polynomials and atmospheric turbulence,” Journal of Optical Society Of America, Vol. 66, No. 3, March 1976, for details) may be calculated. In addition, the first component c₁′ and the angle θ may be calculated as the index indicating the degree of astigmatism.

Thus, the present embodiment can evaluate the astigmatism of the laser beam L in the laser processing apparatus 2 without arranging, in the vicinity of the chuck table 10, a concave mirror, an optical measuring instrument such as a beam profiler or a wavefront sensor, and an optical system which is dedicated to observation and is disposed between the concave mirror and the optical measuring instrument. This can lead to a reduction in cost of the laser processing apparatus 2, and provides an advantage of obviating a need for precise position adjustment work for the concave mirror, the optical measuring instrument, and the optical system dedicated to observation because the concave mirror, the optical measuring instrument, and the optical system are omitted.

The auxiliary storage apparatus stores a fourth program. By executing the fourth program by the processor 64a, the fourth program functions as an astigmatism correcting section 74 (see FIG. 5). When the absolute value of the value of the first component c₁ and the absolute value of the value of the second component c₂ are each larger than a threshold value set in advance, the astigmatism correcting section 74 operates the astigmatism correcting unit 54 to make each of the absolute value of the value of the first component c₁ and the absolute value of the second component c₂ equal to or less than the threshold value.

The respective threshold values of the first component c₁ and the second component c₂ are 10 nm, for example. When the absolute value of the value of the first component c₁ (that is, |c₁|) exceeds 10 nm (for example, when the value of the first component c₁ is-20 nm, 32 nm, or the like), the astigmatism correcting section 74 adjusts Δ of Equation (4) so as to make the absolute value of the value of the first component c₁ equal to or less than 10 nm.

When the absolute value of the value of the second component c₂ (that is, |c₂|) exceeds the threshold value, the astigmatism correcting section 74 adjusts δθ of Equation (5) so as to make the absolute value of the value of the second component c₂ equal to or less than the threshold value. However, in a case of performing processing in which it is obvious that ±45° astigmatism does not produce an adverse effect, the threshold value does not necessarily have to be provided to |c₂|, or δθ does not necessarily have to be adjusted. In addition, in a case where the occurrence of the +45° astigmatism is not expected, c₁′ may be treated as c₁ without the coordinate transformation of Equation (7) being performed, and calculation may be progressed by assuming that θ=0 when the aspect ratio is calculated.

Incidentally, in a case where the first component c₁′ and the angle θ are calculated as the index indicating the degree of astigmatism at a time of calculating astigmatism, both the cylindrical lens 54a and the cylindrical lens 54b may be rotated by −θ, and Δ of Equation (4) may be adjusted such that | c₁′ | becomes less than the threshold value.

Next, the evaluating method for evaluating the astigmatism of the laser beam L in the laser processing apparatus 2 will be described along each step of FIG. 1. First, as illustrated in FIG. 5, the workpiece unit 19 (workpiece 11) is held under suction by the chuck table 10 (holding step S10).

Next, as illustrated in FIG. 5, while the condenser 56 and the chuck table 10 are moved relative to each other along the X-axis direction, the condenser 56 and the chuck table 10 are moved relative to each other along the Z-axis direction such that the condensing point P is positioned at the plurality of height positions located between the first height position Z₁ (see FIG. 6B) and the second height position Z₂ (see FIG. 6C).

At this time, a plurality of processing traces 11c in a spot shape are respectively formed at different positions of the top surface 11a by applying the laser beam L from the condenser 56 to the top surface 11a of the workpiece 11 in timing in which the condenser 56 is disposed at each height position (processing step S20).

Incidentally, the chuck table 10 and the condenser 56 do not necessarily have to be moved at a constant speed. The chuck table 10 may repeat a movement by a predetermined length and a stop, and the condenser 56 may also repeat a movement by a predetermined length and a stop.

Thus, in the processing step S20, the processing traces 11c are formed according to the respective height positions of the condensing point P by (i) positioning the condensing point P at the plurality of height positions by operating the Z-axis direction moving mechanism 34 and thereby moving the condenser 56 and the workpiece 11 relative to each other along the Z-axis direction and (ii) moving the condenser 56 and the workpiece 11 relative to each other along the X-axis direction by operating the X-axis direction moving mechanism 22.

FIG. 5 is a diagram illustrating the holding step S10 and the processing step S20. In the present embodiment, first, the defocus value is set at a positive first value corresponding to the first height position Z₁ (see FIG. 6B), and then a processing trace 11c is formed. Finally, the defocus value is set at a negative second value corresponding to the second height position Z₂ (see FIG. 6C), and then a processing trace 11c is formed. However, the defocus value may be first set at the negative second value, and then a processing trace 11c may be formed, and the defocus value may be finally set at the positive first value, and then a processing trace 11c may be finally formed.

As illustrated in FIG. 5, a plurality of processing traces 11c are discretely formed along the X-axis direction on the top surface 11a after the processing step S20. However, the plurality of processing traces 11c do not necessarily have to be formed so as to be arranged in one row. For example, a plurality of processing traces 11c in a first row and a plurality of processing traces 11c in a second row may be formed so as to be each arranged along the X-axis direction by performing indexing feed along the Y-axis direction as appropriate. Similarly, a plurality of processing traces 11c may each be formed in a first to a third row or a first to a fourth row.

In a case where a plurality of processing traces 11c are formed in N rows or more (where N is a natural number of 2 or more), the defocus value at a time of formation of a first processing trace 11c in a first row is set at the positive first value (or the negative second value), and the defocus value at a time of formation of a final processing trace 11c in an Nth row is set at the negative second value (or the positive first value).

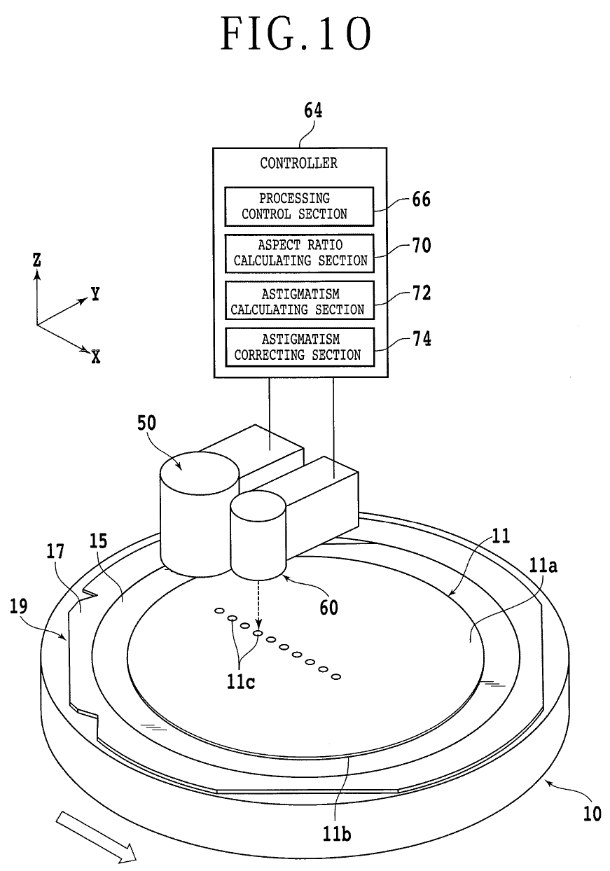

After the processing step S20, an image of each of the processing traces 11c is obtained by imaging the plurality of processing traces 11c by the imaging unit 60 (imaging step S30). FIG. 10 is a diagram illustrating the imaging step S30. In the present embodiment, the imaging unit 60 is disposed above one processing trace 11c, the one processing trace 11c is imaged, and then the chuck table 10 is processing-fed.

Then, the imaging unit 60 is disposed above one other processing trace 11c adjacent to the immediately preceding imaged processing trace 11c, and the one other processing trace 11c is imaged. All of the processing traces 11c are similarly imaged. However, two or more processing traces 11c may be imaged by the imaging unit 60 at a time.

After the image of each of the processing traces 11c is obtained, the above-described aspect ratio calculating section 70 calculates the aspect ratio ε of each of the processing traces 11c (see FIG. 7A and FIG. 7B) and the inclination angle θ of the processing trace 11c from the image of each of the processing traces 11c by subjecting the image of each of the processing traces 11c to image processing (aspect ratio calculating step S40). The image processing performed by the aspect ratio calculating section 70 includes binarization processing, contour extraction processing, and the like.

Next, the astigmatism calculating section 72 calculates the approximate curve 72a on the basis of data on the plurality of height positions of the condensing point P (axis of abscissas in FIG. 8) and the aspect ratios ε of the processing traces 11c corresponding to the respective height positions (axis of ordinates in FIG. 8) (that is, the plurality of dots illustrated in FIG. 8).

Then, under an assumption that the approximate curve 72a and Equation (12) coincide with each other, the astigmatism calculating section 72 calculates the first component c₁′, and then calculates each of the first component c₁ and the second component c₂ (that is, the index indicating the degree of astigmatism) from Equation (9) (astigmatism calculating step S50).

In the experiment illustrated in FIG. 8, the major axes and the minor axes of the processing traces 11c were each along the X-axis direction or the Y-axis direction, and θ=0 (that is, the second component c₂′=0). In addition, D_{X′}=D_{Y′}=D (that is, the laser beam L was cylindrical). In this case, Equation (12) can be simplified as in the following Equation (13).

$$\begin{matrix}[ Math . 13 ] & \\ ε ( {Z}_{DF} ) = \frac{\sqrt{{( \frac{{M}^{2} f λ}{π D} )}^{2} + {[ \frac{D}{2 f} ( {z}_{DF} + \frac{2 {c}_{1}}{{R}^{2}} ) ]}^{2}}}{\sqrt{{( \frac{{M}^{2} f λ}{π D} )}^{2} + {[ \frac{D}{2 f} ( {z}_{DF} - \frac{2 {c}_{1}}{{R}^{2}} ) ]}^{2}}} & ( 13 )\end{matrix}$$

In the experiment illustrated in FIG. 8, M²=1.1, f=50 mm, λ=355 nm, D=3.2 μm, and R=D/2. When the first component c₁ was calculated under an assumption that the approximate curve 72a and Equation (13) coincide with each other, the first component c₁=−37 nm.

The present embodiment can evaluate astigmatism by forming the plurality of processing traces 11c on the top surface 11a of the workpiece 11, and therefore obviates a need for the concave mirror and the like in the vicinity of the chuck table 10. This can lead to a reduction in cost of the laser processing apparatus 2, and also provides an advantage of obviating a need for precise position adjustment work for the concave mirror, the optical measuring instrument, and the optical system dedicated to observation.

As a comparative example, it is conceivable to form a continuous processing trace having the shape of the number 8 in a state in which the pulsed laser beam L is substantially continuously applied from the condenser 56 to the workpiece 11 instead of irradiating the workpiece 11 with the pulsed laser beam L when the condenser 56 is positioned at each of the height positions.

Specifically, a first continuous processing trace is formed by moving the condenser 56 along the Z-axis direction and moving the workpiece 11 along the X-axis direction, and a second continuous processing trace is formed by moving the condenser 56 along the Z-axis direction and moving the workpiece 11 along the Y-axis direction.

In the case of the comparative example, it is necessary to identify the reference height position Z₀ in both the X-axis direction and the Y-axis direction by identifying most constricted positions in the continuous processing traces as viewed in plan. However, it is difficult to identify the constricted positions unless the power of the laser beam L is sufficiently higher than the processing threshold value.

On the other hand, in the present embodiment, it suffices to form the processing traces 11c in a dot shape, and the power of the laser beam L does not need to be made sufficiently higher than the processing threshold value. The present embodiment is more advantageous in this respect.

In addition, in the case of the comparative example, there is also a problem in that it is difficult to identify a constricted position in a processing trace because debris occurring at a time of the laser processing adheres to the processing trace when the continuous processing trace is formed with the power of the laser beam L set sufficiently higher than the processing threshold value. The present embodiment is advantageous also in this respect.

Now, when the absolute value of the first component c₁ is larger than the threshold value (NO in S60), Δ illustrated in Equation (4) is adjusted (astigmatism correcting step S70). After the astigmatism correcting step S70, steps from the processing step S20 to the astigmatism calculating step S50 are performed again, and whether or not the absolute value of the first component c₁ has become equal to or less than the threshold value is checked.

The series of flows from the processing step S20 to the astigmatism calculating step S50 is repeated until the absolute value of the first component c₁ becomes equal to or less than the threshold value. When the absolute value of the first component c₁ has become equal to or less than the threshold value (YES in S60), the flow is ended.

Incidentally, δθ illustrated in Equation (5) is adjusted when the absolute value of the second component c₂ is larger than the threshold value and the second component c₂ is a target for adjustment. Also in this case, the series of flows from the processing step S20 to the astigmatism calculating step S50 is repeated until the absolute value of the second component c₂ becomes equal to or less than the threshold value.

Needless to say, when both the first component c₁ and the second component c₂ are each larger than the threshold value (NO in S60), the absolute value of the first component c₁ is reduced by adjusting Δ, and the absolute value of the second component c₂ is reduced by adjusting δθ.

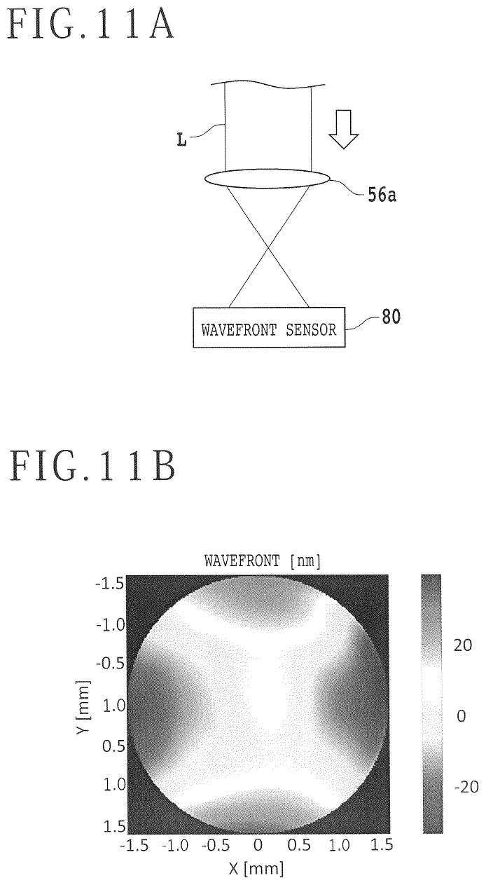

Next, referring to FIG. 11A and FIG. 11B, description will be made of an experiment for verifying whether or not the first component c₁′ calculated from the approximate curve 72a and Equation (12) was an appropriate result. FIG. 11A is a schematic diagram illustrating a measurement of the astigmatism of the laser beam L by using a wavefront sensor 80. In the present verifying experiment, the laser processing apparatus 2 was used to irradiate the wavefront sensor 80, rather than the workpiece 11, with the laser beam L passed through the condensing lens 56a.

FIG. 11B is a diagram two-dimensionally illustrating the wavefront of the laser beam L obtained by using the wavefront sensor 80. Regions in the vicinities of upper and lower ends of a circular region illustrated in FIG. 11B (+90° direction) correspond to +30 nm to +40 nm, regions in the vicinities of left and right ends of the circular region illustrated in FIG. 11B (0°-180° direction) correspond to −40 nm to −30 nm, and the +45° direction and +135° direction of the circular region correspond to approximately 0 nm.

That is, the laser beam L illustrated in FIG. 11B has a saddle-shaped wavefront having a projected region projected to a near side from a paper plane at end portions in the ±90° direction of the circular region and having a depressed region depressed to a far side from the paper plane at end portions in the 0°-180° direction of the circular region.

The result illustrated in FIG. 11B indicates that the astigmatism of the wavefront of the laser beam L used in the experiment illustrated in FIG. 8 is governed by the first component c₁ as astigmatism in the 0°-90° direction and hardly includes the second component c₂ as astigmatism in the ±45° direction.

As a result of expanding the wavefront of FIG. 11B by the Zernike polynomial and quantitatively evaluating the first component c₁, the first component c₁ was-36 nm. This result has an error of 1 nm from a result obtained by FIG. 8 and Equation (13) (the first component c₁=−37 nm).

However, the first component c₁ calculated by using Equation (13) and the first component c₁ calculated by using the wavefront sensor 80 can be said to coincide sufficiently with each other even when a measurement error is taken into consideration. That is, it has become apparent that the calculating method using Equation (13) is an appropriate method.

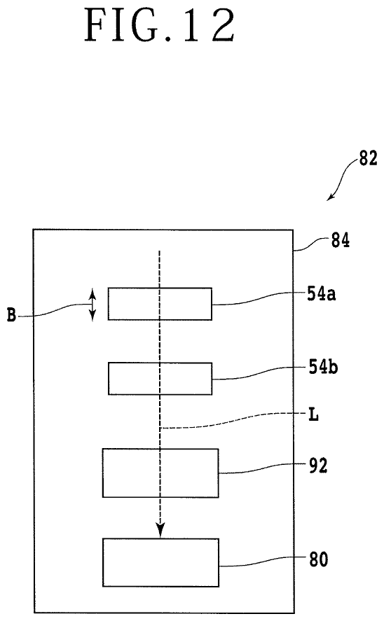

Next, description will be made of an experiment for confirming that δc₁ as an amount of change in the first component c₁ conforms to the above Equation (4) when the distance between the flat surfaces 54a₁ and 54b₁ in the pair of cylindrical lenses 54a and 54b illustrated in FIG. 3B is changed by Δ from 2f. FIG. 12 is a plan view illustrating an outline of an experiment apparatus 82 that adjusts an amount of change in the distance between the pair of cylindrical lenses 54a and 54b and the index indicating the degree of astigmatism (first component c₁ as astigmatism in the 0°-90° direction). Incidentally, constituent elements of the experiment apparatus 82 are simplified in FIG. 12.

The experiment apparatus 82 has an optical bench 84 to which optical elements can be fixed. On the optical bench 84, the cylindrical lens 54a is fixed so as to be movable in an arrow B direction along the axis 54c (see FIG. 3B), and the cylindrical lens 54b is fixed so as not to be moved in the arrow B direction.

The laser beam L passed through the pair of cylindrical lenses 54a and 54b passes through a reflective neutral density (ND) filter 92, and enters the wavefront sensor 80. Incidentally, the ND filter 92 and the wavefront sensor 80 are fixed to the optical bench 84. The distance between the pair of cylindrical lenses 54a and 54b was changed from 2f by using the experiment apparatus 82, and the first component c₁ was quantitatively evaluated by the wavefront sensor 80.

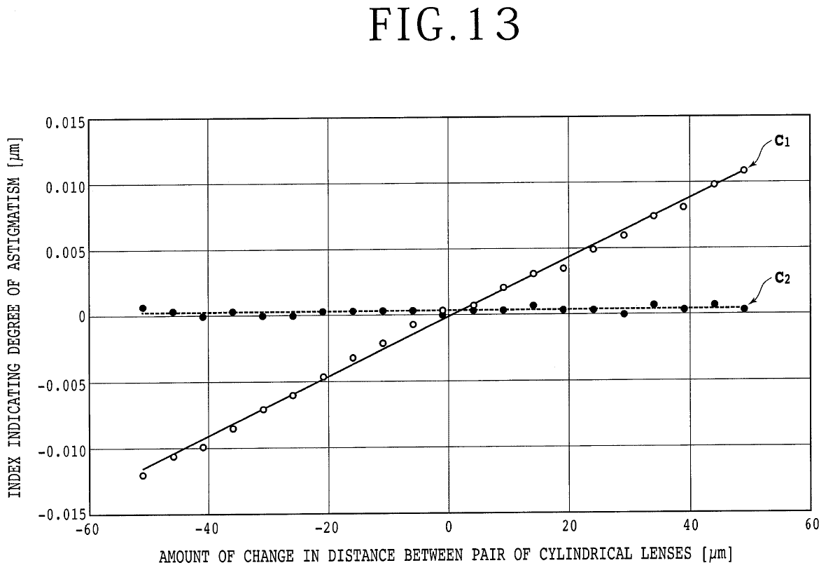

FIG. 13 is an experiment result illustrating amounts of change in the distance between the pair of cylindrical lenses 54a and 54b (axis of abscissas) and the index indicating the degree of astigmatism (that is, the first component c₁ and the second component c₂) (axis of ordinates). Incidentally, the axis of abscissas indicates the magnitude of the amount of change from 2f (f is the focal length of each of the cylindrical lenses 54a and 54b).

In the present experiment, the cylindrical lens 54b was moved such that the distance between the pair of cylindrical lenses 54a and 54b was increased or decreased with respect to the reference position (that is, a change amount of zero from 2f). As a result, as illustrated in FIG. 13, the first component c₁ as astigmatism in the 0°-90° direction changed substantially linearly, while the second component c₂ as astigmatism in the +45° direction did not substantially change. That is, it was indicated that only the first component c₁ can be changed by changing the distance between the pair of cylindrical lenses 54a and 54b without changing the second component c₂.

Incidentally, in the foregoing embodiment and the experiments, description has been made of the laser beam L whose cross section in the traveling direction is circular or elliptic. However, the shape of the cross section of the laser beam L is not limited to this.

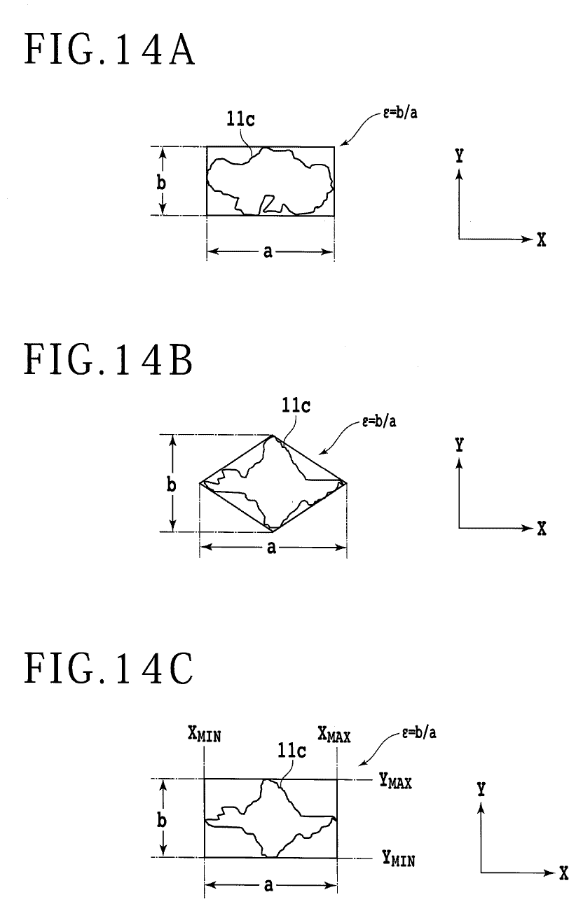

FIG. 14A is a diagram illustrating the aspect ratio ε of a processing trace 11c according to a first modification. FIG. 14A illustrates an example in which the aspect ratio ε is calculated after the processing trace 11c is approximated to a rectangular shape. In this case, the aspect ratio ε of the processing trace 11c, that is, (Length of Processing Trace 11c along Y-axis Direction)/(Length of Processing Trace 11c along X-axis Direction) is b/a.

FIG. 14B is a diagram illustrating the aspect ratio ε of a processing trace 11c according to a second modification. FIG. 14B illustrates an example in which the aspect ratio ε is calculated after the processing trace 11c is approximated to a rhombic shape. Also in this case, the aspect ratio ε of the processing trace 11c is b/a.

FIG. 14C is a diagram illustrating the aspect ratio ¿ of a processing trace 11c according to a third modification. As in the example illustrated in FIG. 14A, FIG. 14C illustrates an example in which the aspect ratio ¿ is calculated after the processing trace 11c is approximated to a rectangular shape. However, in FIG. 14C, the aspect ratio calculating section 70 subjects an image obtained by the imaging unit 60 to binarization processing, then obtains coordinate information of a contour of the processing trace 11c, and calculates the aspect ratio ε from the coordinate information.

More specifically, the length of the processing trace 11c along the Y-axis direction is calculated as a difference between the coordinate of an upper end of the one processing trace 11c (Y_{MAX}) and the coordinate of a lower end thereof (Y_{MIN}) (that is, Y_{MAX}−Y_{MIN}), and the length of the processing trace 11c along the X-axis direction is calculated as a difference between the coordinate of a right end of the one processing trace 11c (X_{MAX}) and the coordinate of a left end thereof (X_{MIN}) (that is, X_{MAX}−X_{MIN}).

Then, the aspect ratio ε is calculated as (Length of Processing Trace 11c along Y-axis Direction)/(Length of Processing Trace 11c along X-axis Direction)=(Y_{MAX}−Y_{MIN})/(X_{MAX}−X_{MIN}). When the aspect ratio calculating section 70 thus calculates the aspect ratio ε from the image obtained by the imaging unit 60, the aspect ratio ε can be calculated automatically also for a processing trace 11c having a given shape without being limited to a predetermined shape such as an ellipse, a rectangular shape, or a rhombic shape.

### Second Embodiment

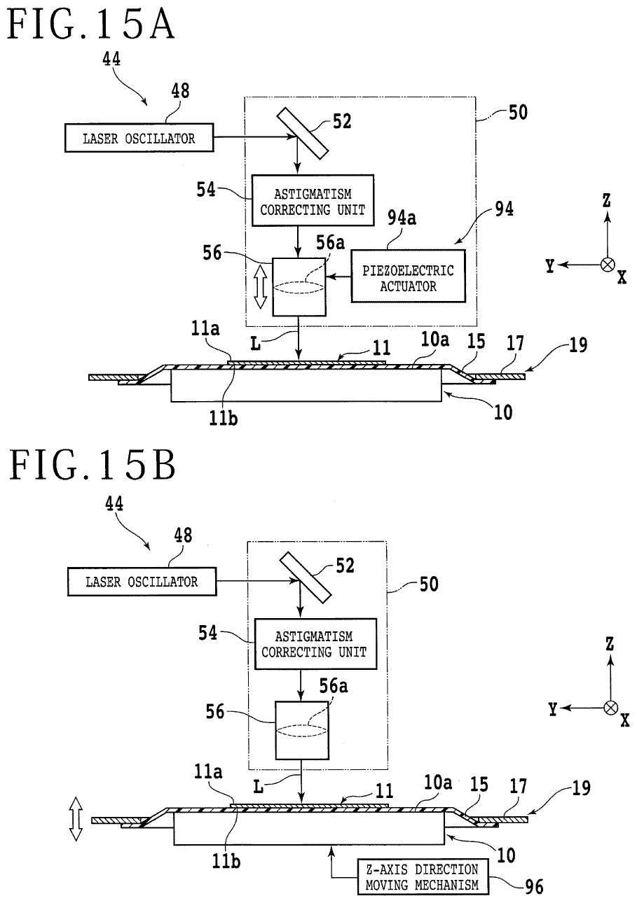

Next, a second embodiment will be described with reference to FIG. 15A. FIG. 15A is a side view illustrating a Z-axis direction moving mechanism (first moving mechanism) 94 according to the second embodiment, which moves the condenser 56 and the chuck table 10 relative to each other along the Z-axis direction (first direction).

The Z-axis direction moving mechanism 94 according to the second embodiment includes a piezoelectric actuator 94a that moves the condenser 56 along the Z-axis direction. The piezoelectric actuator 94a moves the condenser 56 along the Z-axis direction in a range of 1.0 μm to 20 μm, for example. The second embodiment is different from the first embodiment in that the second embodiment includes the Z-axis direction moving mechanism 94. The second embodiment may otherwise be the same as the first embodiment. The Z-axis direction moving mechanism 34 may be used in conjunction in the second embodiment.

### Third Embodiment

Next, a third embodiment will be described with reference to FIG. 15B. FIG. 15B is a side view illustrating a Z-axis direction moving mechanism (first moving mechanism) 96 according to the third embodiment, which moves the condenser 56 and the chuck table 10 relative to each other along the Z-axis direction (first direction).

The Z-axis direction moving mechanism 96 according to the third embodiment includes, for example, a ball screw type moving mechanism (not illustrated) that moves the chuck table 10 along the Z-axis direction. The Z-axis direction moving mechanism 96 is, for example, supported by the X-axis direction moving table 26, and moves the chuck table 10 and the support base 32 (see FIG. 1) along the Z-axis direction.

The third embodiment is different from the first embodiment in that the third embodiment includes the Z-axis direction moving mechanism 96. The third embodiment may otherwise be the same as the first embodiment. The Z-axis direction moving mechanism 34 may be used in conjunction in the third embodiment.

### Fourth Embodiment

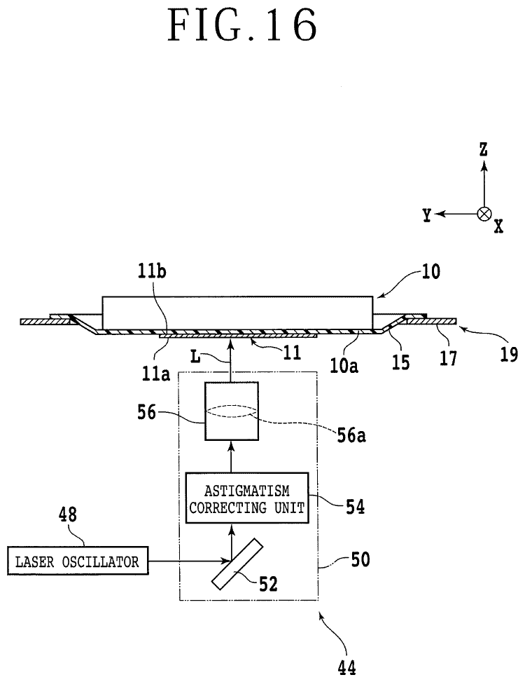

Next, a fourth embodiment will be described with reference to FIG. 16. FIG. 16 is a schematic diagram illustrating the laser beam irradiating unit 44 and the chuck table 10 according to the fourth embodiment. In the fourth embodiment, the top surface 11a of the workpiece 11 held under suction by the chuck table 10 disposed such that the holding surface 10a faces downward is irradiated with the laser beam L upward from below.

However, as in the first embodiment, the chuck table 10 is movable in the XY plane direction, and the laser beam irradiating unit 44 is movable along the Z-axis direction. Incidentally, the condenser 56 may be moved along the Z-axis direction as in the second embodiment, and the chuck table 10 may be moved along the Z-axis direction as in the third embodiment.

The fourth embodiment is different from the first embodiment in that the laser beam irradiating unit 44 and the chuck table 10 are vertically inverted as compared with the first embodiment. The fourth embodiment may otherwise be the same as the first embodiment.

The second, third, and fourth embodiments can also evaluate astigmatism by forming a plurality of processing traces 11c on the top surface 11a, and therefore obviate a need for the concave mirror and the like in the vicinity of the chuck table 10. This can lead to a reduction in cost of the laser processing apparatus 2, and also provides an advantage of obviating a need for precise position adjustment work for the concave mirror, the optical measuring instrument, and the optical system dedicated to observation.

Besides, structures, methods, and the like according to the foregoing embodiments can be modified and implemented as appropriate without departing from the objective scope of the present invention. For example, in place of the chuck table 10 that holds the workpiece unit 19 under suction by a negative pressure, it is possible to adopt a holding structure (holding unit) that holds the workpiece unit 19 in a state in which the holding structure supports the workpiece unit 19 at substantially three points, an electrostatic chuck (holding unit) not illustrated which holds the workpiece unit 19 under suction by an electrostatic force, or the like.

In addition, the astigmatism correcting unit 54 does not necessarily have to be disposed in the head unit 50. The astigmatism correcting unit 54 may be disposed outside the head unit 50. The astigmatism correcting unit 54 may be disposed within the casing 46 that constitutes the laser beam irradiating unit 44.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. An evaluating method for evaluating astigmatism of a laser beam in a laser processing apparatus, the evaluating method comprising:
a processing step of forming a plurality of processing traces each having a spot shape by irradiating different positions of an exposed surface of a workpiece with the laser beam according to respective height positions of a condensing point of the laser beam by positioning the condensing point at a plurality of the height positions located between a first height position separated from a reference height position where the condensing point of the laser beam is located at the exposed surface of the workpiece by a predetermined distance in one direction of a first direction as a direction of irradiation of the workpiece with the laser beam and a second height position separated from the reference height position by a predetermined distance in another direction opposite from the one direction in the first direction, and moving a condenser of a laser beam irradiating unit and the workpiece relative to each other along a second direction intersecting the first direction, the condensing point being positioned at the plurality of height positions by moving the condenser and the workpiece relative to each other along the first direction;
an imaging step of obtaining an image of each of the processing traces by imaging the plurality of processing traces;
an aspect ratio calculating step of calculating an aspect ratio of each of the processing traces from the image of each of the processing traces; and
an astigmatism calculating step of calculating an index indicating a degree of the astigmatism on a basis of the plurality of height positions of the condensing point and the aspect ratio of each of the processing traces.

2. A laser processing apparatus comprising:
a holding unit configured to hold a workpiece;
a laser beam irradiating unit including a laser oscillator and a condenser for condensing a laser beam emitted from the laser oscillator;
a first moving mechanism configured to move the condenser and the holding unit relative to each other along a first direction as a direction of irradiation of the workpiece with the laser beam;
a second moving mechanism configured to move the condenser and the holding unit relative to each other along a second direction intersecting the first direction;
an imaging unit configured to image the workpiece held by the holding unit; and
a controller including a processor and a memory, wherein
the controller includes
a processing control section configured to form a plurality of processing traces each having a spot shape by irradiating different positions of an exposed surface of the workpiece with the laser beam according to respective height positions of a condensing point of the laser beam by positioning the condensing point at a plurality of the height positions located between a first height position separated from a reference height position where the condensing point is located at the exposed surface of the workpiece by a predetermined distance in one direction of the first direction and a second height position separated from the reference height position by a predetermined distance in another direction opposite from the one direction in the first direction, and moving the condenser and the workpiece relative to each other along the second direction by operating the second moving mechanism, the condensing point being positioned at the plurality of height positions by moving the condenser and the workpiece relative to each other along the first direction by operating the first moving mechanism,
an aspect ratio calculating section configured to calculate an aspect ratio of each of the processing traces from an image of each of the plurality of processing traces imaged by the imaging unit, and
an astigmatism calculating section configured to calculate an index indicating a degree of astigmatism on a basis of the plurality of height positions of the condensing point and the aspect ratio of each of the processing traces.

3. The laser processing apparatus according to claim 2, wherein
the laser beam irradiating unit further includes an astigmatism correcting unit configured to correct the astigmatism, and
the controller further includes
an astigmatism correcting section configured to, when an absolute value of the index calculated by the astigmatism calculating section and indicating the degree of the astigmatism is larger than a threshold value, make the absolute value of the index equal to or less than the threshold value by operating the astigmatism correcting unit.

4. The laser processing apparatus according to claim 3, wherein
the astigmatism correcting unit includes a spatial light phase modulator or a pair of convex cylindrical lenses.
